(19) United States
(12) Patent Application Publication
(10) Pub. No.: US 2003/0131472 A1
(43) Pub. Date: Jul. 17, 2003

(54) Method of fabricating a multi-layer circuit board assembly

(75) Inventors: Yu-Chiang Cheng, Taipei City (TW); Jong-Kuei Chen, Hua-Lien Hsien (TW)

Correspondence Address: MERCHANT & GOULD PC, P.O. BOX 2903, MINNEAPOLIS, MN, 55402-0903, US

(73) Assignee: Mitac international Corp., Hsinchu Hsien (TW)

(21) Appl. No.: 10/050,621

(22) Filed: Jan. 15, 2002

(51) Int. Cl. H05K 3/36; H05K 3/34

(52) U.S. Cl. 29/840; 29/830; 29/831

(57) ABSTRACT

In a method of fabricating a multi-layer circuit board assembly, at least two multi-layer circuit board modules are provided. Each of the modules has a lateral edge provided with a plurality of solder pads that are connected electrically with module interconnect circuit traces on a respective one of the modules. The modules are stacked one upon the other, and are bonded together such that the solder pads of one of the modules are connected to registered ones of the solder pads of the other one of the modules, thereby establishing electrical connection among the circuit traces on the modules.

### BACKGROUND OF THE INVENTION

1. Field of the Invention

The invention relates to a method of fabricating a multi-layer circuit board assembly, more particularly to a method of fabricating a multi-layer circuit board assembly, which involves relatively simple steps, and less costs and time.

2. Description of the Related Art

Multi-layer circuit boards are relatively difficult and costly to manufacture, and the difficulty and costs increase with the number of layers of the circuit boards. It is even more complicated to fabricate a multi-layer circuit board with blind vias, i.e., vias for signal interconnect between inner substrate layers, and filled vias, i.e., through-hole vias that are filled to prevent entry of solder during solder reflow. In the former, vias are pre-formed in the inner substrate layers that are to be interconnected by drilling before all the substrate layers are bonded. In the latter, through vias are formed in the top and bottom substrate layers by drilling, and the top and bottom substrate layers are press-bonded to sandwich other inner substrate layers therebetween. A filler material is then disposed in the through-hole vias to fill the latter. The forming of the blind vias and the filled vias is becoming more and more difficult with the current trend toward an increasing number of substrate layers of a multi-layer circuit board.

### SUMMARY OF THE INVENTION

Therefore, the main object of the present invention is to provide a method of fabricating a multi-layer circuit board assembly in a simple and efficient manner and at less costs and time.

Accordingly, the method of fabricating a multilayer circuit board assembly of the present invention includes:

providing a first multi-layer circuit board module which has opposing first upper and lower surfaces, and a first lateral edge joining the first upper and lower surfaces, the first upper surface being formed with a plurality of first module interconnect circuit traces that are led toward the first lateral edge;

providing a second multi-layer circuit board module which has opposing second upper and lower surfaces, and a second lateral edge joining the second upper and lower surfaces, the second upper surface being formed with a plurality of second module interconnect circuit traces that are led toward the second lateral edge;

forming a plurality of first solder pads on the first lateral edge of the first multi-layer circuit board module such that each of the first solder pads is connected electrically to a respective one of the first module interconnect circuit traces;

forming a plurality of second solder pads on the second lateral edge of the second multi-layer circuit board module such that each of the second solder pads is connected electrically to a respective one of the second module interconnect circuit traces;

stacking the second multi-layer circuit board module on top of the first multi-layer circuit board module such that the second lower surface is superimposed on the first upper surface and such that the second solder pads are registered with the first solder pads, respectively; and

bonding each of the second solder pads to the registered one of the first solder pads so as to interconnect the first and second module interconnect circuit traces.

### BRIEF DESCRIPTION OF THE DRAWINGS

Other features and advantages of the present invention will become apparent in the following detailed description of the preferred embodiments with reference to the accompanying drawings, of which:

FIG. 1 is a fragmentary exploded perspective view of the first preferred embodiment of a method of fabricating a multi-layer circuit board assembly according to the present invention;

FIG. 2 is a fragmentary side view of the multi-layer circuit board assembly after bonding;

FIG. 3 is a fragmentary exploded perspective view of the second preferred embodiment of a method of fabricating a multi-layer circuit board assembly according to the present invention;

FIG. 4 is fragmentary perspective view of the multi-layer circuit board assembly of FIG. 3 after bonding;

FIG. 5 is a fragmentary exploded perspective view illustrating multi-layer circuit board modules formed with vias; and

FIG. 6 is a fragmentary side view showing bonding of the multi-layer circuit board modules with vias to form a multi-layer circuit board assembly.

### DETAILED DESCRIPTION OF THE PREFERRED EMBODIMENTS

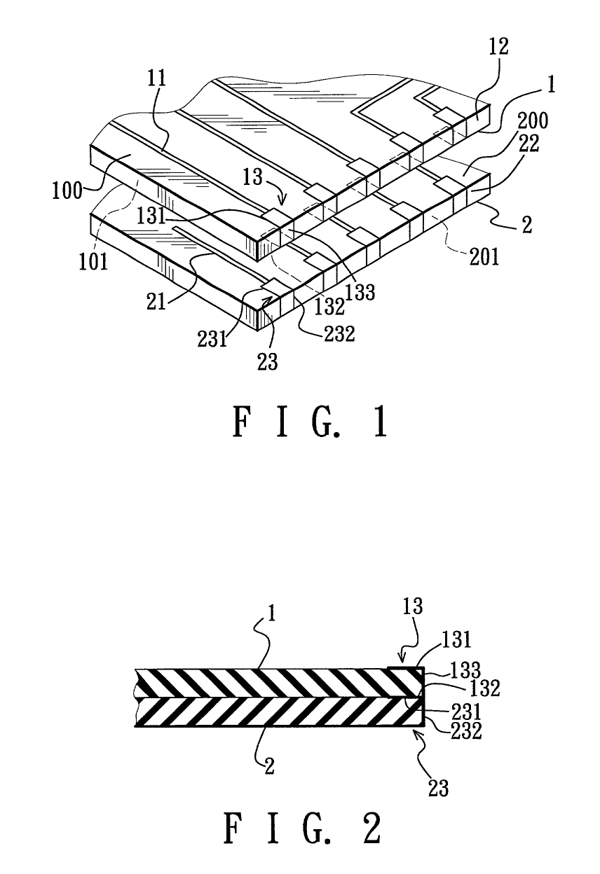

The present invention is directed to a method of fabricating a multi-layer circuit board assembly by bonding at least two multi-layer circuit board modules together, such as two four-layer circuit board modules. For the sake of clarity, the multi-layer circuit board modules are shown in the drawings as single press-bonded structures. Referring to FIGS. 1 and 2, the first preferred embodiment of the method according to the present invention includes the step of providing first and second multi-layer circuit board modules 2, 1. The first multi-layer circuit board module 2 has opposing first upper and lower surfaces 200, 201, and a substantially flat first lateral edge 22 joining the first upper and lower surfaces 200, 201. The first upper surface 200 is formed with a plurality of first module interconnect circuit traces 21 that are led toward the first lateral edge 22. Likewise, the second multi-layer circuit board module 1 has opposing second upper and lower surfaces 100, 101, and a substantially flat second lateral edge 12 joining the second upper and lower surfaces 100, 101. The second upper surface 100 is formed with a plurality of second module interconnect circuit traces 11 that are led toward the second lateral edge 12. Subsequently, a plurality of first solder pads 23 are formed on the first lateral edge 22 of the first multi-layer circuit board module 2 such that each of the first solder pads 23 is connected electrically to a respective one of the first module interconnect circuit traces 21. Each of the first solder pads 23 includes a planar first bonding portion 232 formed on the first lateral edge 22, and a connecting portion 231 extending transversely from the first bonding portion 232 to the first upper surface 200 to connect electrically with a respective one of the first module interconnect circuit traces 21. Similarly, a plurality of second solder pads 13 are formed on the second lateral edge 12 of the second multi-layer circuit board module 1 such that each of the second solder pads 13 is connected electrically to a respective one of the second module interconnect circuit traces 11. Each of the second solder pads 13 includes a planar second bonding portion 133 formed on the second lateral edge 12, and upper and lower connecting parts 131, 132 extending transversely from the second bonding portion 133 to the second upper and lower surfaces 100, 101, respectively. The upper connecting parts 131 connect electrically with a respective one of the second module interconnect circuit traces 11. Then, the second multi-layer circuit board module 1 is stacked on top of the first multi-layer circuit board module 2 such that the second lower surface 101 is superimposed on the first upper surface 200 and such that the second solder pads 13 are registered with the first solder pads 23, respectively. Each of the lower connecting parts 132 is in contact with the connecting portion 231 of the registered one of the first solder pads 23. Lastly, each of the second solder pads 13 is bonded to the registered one of the first solder pads 23 by electroplating so as to interconnect the first and second module interconnect circuit traces 21, 11, thereby achieving a multi-layer circuit board assembly, such as that shown in FIG. 2.

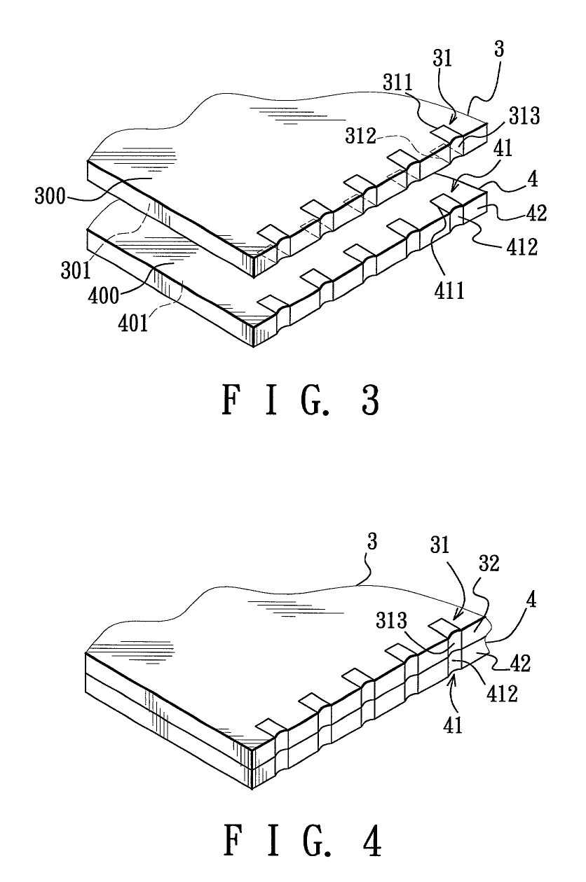

Reference is made to FIG. 3, which shows the second preferred embodiment of a method of fabricating a multi-layer circuit board assembly according to the present invention. As in the first preferred embodiment, there are provided first and second multi-layer circuit board modules 4, 3, and a plurality of first and second solder pads 41, 31 are respectively formed on first and second lateral edges 42, 32 of the first and second multi-layer circuit board modules 4, 3. Each of the first solder pads 41 includes a first bonding portion 412 and a connecting portion 411. Each of the second solder pads 31 includes a second bonding portion 313 and upper and lower connecting parts 311, 312. The major difference between the first and second preferred embodiments resides in that the first lateral edge 42 is formed with a plurality of concave recesses that extend between first upper and lower surfaces 400, 401 of the first multi-layer circuit board module 4, and the second lateral edge 32 is formed with a plurality of concave recesses that extend between second upper and lower surfaces 300, 301 of the second multi-layer circuit board module 3. Each of the first and second bonding portions 412, 313 lines a respective one of the concave recesses. By virtue of this configuration, when the first and second multi-layer circuit board modules 4, 3 are bonded as shown in FIG. 4, a larger contact joint between the first and second bonding portions 412, 313 can be achieved.

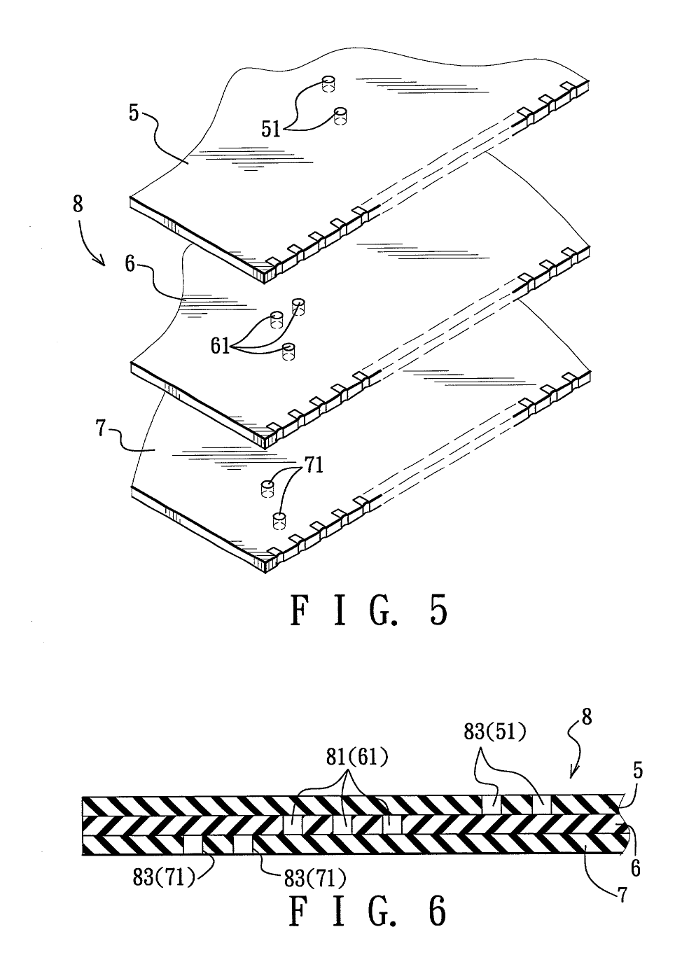

In addition, the present invention facilitates the making of blind vias and through-hole vias in the multi-layer circuit board assembly. Referring to FIGS. 5 and 6, in a multi-layer circuit board assembly 8 comprising three multi-layer circuit board modules 5, 6, 7, prior to bonding, through holes can be formed in one or more of the multi-layer circuit board modules 5, 6, 7. In the example as illustrated, through holes 51, 61, 71 are formed in the multi-layer circuit board modules 5, 6, 7, respectively. After the three multi-layer circuit board modules 5, 6, 7 are bonded to form the multi-layer circuit board assembly 8, as shown in FIG. 6, the through holes 61 in the second multi-layer circuit board module 6 that is sandwiched between the first and third multi-layer circuit board modules 5, 7 can serve as blind vias 81, while the through holes 51, 71 in the first and third multi-layer circuit board modules 5, 7 can serve as through-hole vias 83 that are to be filled so as to prevent entry of solder thereinto during solder reflow.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

We claim:

1. A method of fabricating a multi-layer circuit board assembly, comprising:
providing a first multi-layer circuit board module which has opposing first upper and lower surfaces, and a first lateral edge joining said first upper and lower surfaces, said first upper surface being formed with a plurality of first module interconnect circuit traces that are led toward said first lateral edge;
providing a second multi-layer circuit board module which has opposing second upper and lower surfaces, and a second lateral edge joining said second upper and lower surfaces, said second upper surface being formed with a plurality of second module interconnect circuit traces that are led toward said second lateral edge;
forming a plurality of first solder pads on said first lateral edge of said first multi-layer circuit board module such that each of said first solder pads is connected electrically to a respective one of said first module interconnect circuit traces;
forming a plurality of second solder pads on said second lateral edge of said second multi-layer circuit board module such that each of said second solder pads is connected electrically to a respective one of said second module interconnect circuit traces;
stacking said second multi-layer circuit board module on top of said first multi-layer circuit board module such that said second lower surface is superimposed on said first upper surface and such that said second solder pads are registered with said first solder pads, respectively; and
bonding each of said second solder pads to the registered one of said first solder pads so as to interconnect said first and second module interconnect circuit traces.

2. The method as claimed in claim 1, wherein:
each of said first solder pads includes a first bonding portion formed on said first lateral edge, and a connecting portion extending transversely from said first bonding portion to said first upper surface to connect electrically with a respective one of said first module interconnect circuit traces; and
each of said second solder pads includes a second bonding portion formed on said second lateral edge, and upper and lower connecting parts extending transversely from said second bonding portion to said second upper and lower surfaces, respectively, said upper connecting parts connecting electrically with a respective one of said second module interconnect circuit traces, each of said lower connecting parts being in contact with said connecting portion of the registered one of said first solder pads.

3. The method as claimed in claim 2, wherein said first and second lateral edges are substantially flat, and said first and second bonding portions are planar.

4. The method as claimed in claim 2, wherein said first lateral edge is formed with a plurality of concave recesses that extend between said first upper and lower surfaces, and said second lateral edge is formed with a plurality of concave recesses that extend between said second upper and lower surfaces, each of said first and second bonding portions lining a respective one of said concave recesses.

5. The method as claimed in claim 1, wherein said first and second solder pads are bonded together by electroplating.
